(19) United States
(12) Patent Application Publication
(10) Pub. No.: US 2010/0123469 A1
(43) Pub. Date: May 20, 2010

(54) SYSTEM AND METHOD FOR PROTECTING CIRCUIT BOARDS

(76) Inventor: Edward Craig Hyatt, Durham, NC (US)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 12/273,801

(22) Filed: Nov. 19, 2008

(51) Int. Cl. G01R 27/08; H05K 1/18

(52) U.S. Cl. 324/705; 174/260

(57) ABSTRACT

A system and method for protecting electrical contact points on a circuit board from tampering and probing. The system includes a protective cover preventing access to electrical contact points on the circuit board. The protective cover includes: at least one nonconductive material layer, a plurality of electrical contacts coupled to the circuit board, and an irregular resistance pattern joined with the at least one layer of nonconductive material and coupled to the plurality of the electrical contacts. The system further includes a controller that is coupled to the plurality of electrical contacts. The system selects two electrical contacts and determines the resistance between the two electrical contacts. The determined resistance is then compared to a baseline resistance determination for the same set of electrical contacts. A security breach can be identified by a change in resistance from the baseline.

### TECHNICAL FIELD OF THE INVENTION

The present invention relates generally to electronic devices and, more particularly, to a system and method for preventing tampering with circuit boards in electronic devices, and in particular portable electronic devices, by preventing access to electrical contact points on circuit boards of the electronic devices.

### DESCRIPTION OF THE RELATED ART

In recent years, portable electronic devices, such as mobile phones, personal digital assistants, mobile terminals, etc., have grown in popularity and continue to grow in popularity. At least anecdotally, it can be said that everyone seems to have a mobile phone these days. As the popularity of portable electronic devices continues to grow, mobile phones and networks are being enhanced to provide services beyond voice services. For example, portable electronic devices often include cameras, text messaging capability, Internet browsing functionality, electronic mail capability, video playback capability, audio playback capability, image display capability and hands-free headset interfaces.

Portable electronic devices are appealing to users because of their capability to serve as powerful communication and data service tools. As portable electronic devices become more a part of daily life, portable electronic device security becomes increasingly important.

### SUMMARY

Portable electronic devices, and particularly portable wireless devices, can be susceptible to hacking or cloning. Any exposed electrical interface is a potential security breach. For example, portable electronic devices may be hacked by manipulating memory control lines to put the phone in test/boot mode. Another method for hacking portable electronic devices involves tracing address, data, or control buses to reverse engineer software on the device. In addition, hackers can monitor Subscriber Identity Module (“SIM”) or SmartCard pins to decode security transactions. It is desirable to prevent hacking and reverse engineering of portable electronic devices. One way to protect against hacking is to protect electrical contact points of the portable electronic device from probing.

One aspect of the present invention relates to a system for protecting electrical contact points on a circuit board. The system includes a protective cover preventing access to electrical contact points on the circuit board. The protective cover includes: at least one nonconductive material layer, a plurality of electrical contacts coupled to the circuit board, and an irregular resistance pattern joined with the at least one layer of nonconductive material and coupled to the plurality of the electrical contacts. The system further includes a controller that is coupled to the plurality of electrical contacts. The controller is configured to: periodically determine the resistance between selected electrical contacts, compare the determined resistance between the selected electrical contacts with a prior determined resistance between the selected electrical contacts, and indicate a security breach based upon a change in the prior determined resistance and the periodically determined resistance.

According to another aspect, the system further includes a memory for storing the prior determined resistance between the selected electrical contacts. In addition, the controller may be further configured to store the periodically determined resistance in memory. Also, the periodically determined resistance from a first determination may be the prior determined resistance in a second determination.

According to another aspect, the controller is further configured to sequentially select the selected electrical contacts.

According to another aspect, the irregular resistance pattern comprises scan lines between the selected electrical contacts.

According to another aspect, the system further includes an analog to digital converter for converting signals received over scan lines to digital form.

According to another aspect, the nonconductive material layer is a mesh layer.

According to another aspect, the irregular resistance pattern comprises resistive ink printed on the nonconductive material layer.

According to another aspect, the irregular resistance pattern is embedded within multiple layers of nonconductive material.

According to another aspect, the irregular resistance pattern is a randomized pattern.

According to another aspect, the nonconductive material layer further includes at least one opening through which cables connected to the circuit board can exit the protective cover.

According to another aspect, a Subscriber Identity Module card socket includes the electrical contact points.

Another aspect of the present invention relates to a multilayer tamper evidencing circuit board that includes: a first circuit board layer; a second circuit board layer; and a tamper evidencing layer between the first circuit board layer and the second circuit board layer. The tamper evidencing layer includes: at least one nonconductive material layer, a plurality of electrical contacts coupled to at least one of the first circuit board layer or the second circuit board layer, and an irregular resistance pattern joined with the at least one layer of nonconductive material and coupled to the plurality of the electrical contacts.

According to another aspect, the multilayer tamper evidencing circuit board further includes a controller coupled to the plurality of electrical contacts and configured to: periodically determine the resistance between selected electrical contacts, compare the determined resistance between the selected electrical contacts with a prior determined resistance between the selected electrical contacts, and indicate a security breach based upon a change in the prior determined resistance and the periodically determined resistance.

Another aspect of the present invention relates to a method for protecting electrical contact points on a circuit board including: covering electrical contact points on the circuit board with a protective cover including: at least one nonconductive material layer, a plurality of electrical contacts coupled to the circuit board, and an irregular resistance pattern joined with the at least one layer of nonconductive material and coupled to the plurality of the electrical contacts. The method further includes selecting a first set of two of the plurality of electrical contacts; determining the resistance between the first set of electrical contacts; comparing the determined resistance between the first set of electrical contacts with a prior determined resistance between the first set of electrical contacts; and indicating a security breach based upon a change in the prior determined resistance between the first set of electrical contacts and the determined resistance between the first set of electrical contacts.

According to another aspect, the method further includes storing in memory the prior determined resistance between the selected electrical contacts.

According to another aspect, the method further includes converting the determined resistance from analog to digital form.

According to another aspect, the method further includes: selecting a second set of two of the plurality of electrical contacts such that at least one of the second set of two electrical contacts is different from the electrical contacts in the first set of two electrical contacts; determining the resistance between the second set of two contacts; comparing the determined resistance between the second set of two contacts with a prior determined resistance between the second set of two contacts; and indicating a security breach based upon a change in the prior determined resistance between the second set of two contacts and the determined resistance between the second set of two contacts. In addition, these steps may be repeated for a plurality of different desired second sets of two of the plurality electrical contacts.

Another aspect of the present invention relates to a multilayer tamper evidencing circuit board that includes: a first circuit board layer; a second circuit board layer; and a tamper evidencing layer between the first circuit board layer and the second circuit board layer. The tamper evidencing layer includes: at least one nonconductive material layer, a plurality of electrical contacts coupled to at least one of the first circuit board layer or the second circuit board layer, and an irregular resistance pattern joined with the at least one layer of nonconductive material and coupled to the plurality of the electrical contacts.

According to another aspect, the multilayer tamper evidencing circuit board further includes a controller coupled to the plurality of electrical contacts and configured to: periodically determine the resistance between selected electrical contacts, compare the determined resistance between the selected electrical contacts with a prior determined resistance between the selected electrical contacts, and indicate a security breach based upon a change in the prior determined resistance and the periodically determined resistance.

These and further features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the claims appended thereto.

Features that are described and/or illustrated with respect to one embodiment may be used in the same way or in a similar way in one or more other embodiments and/or in combination with or instead of the features of the other embodiments.

It should be emphasized that the term “comprises/comprising” when used in this specification is taken to specify the presence of stated features, integers, steps or components but does not preclude the presence or addition of one or more other features, integers, steps, components or groups thereof.

### BRIEF DESCRIPTION OF THE DRAWINGS

Many aspects of the invention can be better understood with reference to the following drawings. The components in the drawings are not necessarily to scale, emphasis instead being placed upon clearly illustrating the principles of the present invention. Likewise, elements and features depicted in one drawing may be combined with elements and features depicted in additional drawings. Moreover, in the drawings, like reference numerals designate corresponding parts throughout the several views.

FIG. 1 is a schematic view of a mobile telephone as exemplary electronic equipment in accordance with an aspect of the invention;

FIG. 2 is a schematic block diagram of the relevant portions of the mobile telephone of FIG. 1 in accordance with an aspect of the invention;

FIGS. 3A-C are views of a protected circuit board according to the invention;

FIG. 4 is a closer view of a protective cover, such as that illustrated in FIGS. 3A-C;

FIG. 5 is a diagrammatic illustration of an exemplary system for protecting electrical contacts on a circuit board; and

FIG. 6 is a diagrammatic illustration of an embodiment of a system having protective layers between layers of a circuit board.

### DETAILED DESCRIPTION OF EMBODIMENTS

The present invention will now be described with reference to the drawings, wherein like reference numerals are used to refer to like elements throughout.

The term “electronic equipment” includes, among other things, portable radio communication equipment. The term “portable radio communication equipment,” which herein after is referred to as a “mobile radio terminal,” includes all equipment such as mobile telephones, pagers, communicators, i.e., electronic organizers, personal digital assistants (PDAs), smartphones, portable communication apparatus or the like.

In the present application, the invention is described primarily in the context of a mobile telephone. It will be appreciated, however, that the electronic equipment invention is not intended to be limited to a mobile telephone and can be any type of electronic equipment.

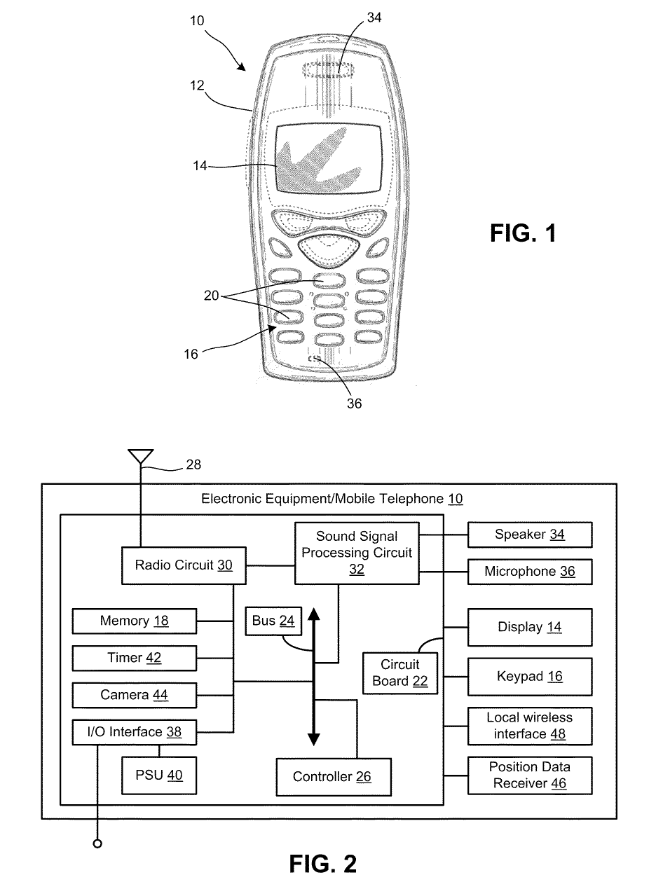

Referring initially to FIG. 1, an electronic equipment item 10 is shown in accordance with the present invention. The electronic equipment in the exemplary embodiment is a mobile telephone and will be referred to as the mobile telephone 10. The mobile telephone 10 is shown as having a “brick” or “block” form factor housing 12, but it will be appreciated that other type housings, such as a clamshell housing or a slide-type housing, may be utilized without departing from the scope of the invention. It should also be understood that present invention may be utilized with any type of electronic equipment having electrical contacts that can be probed, such as electrical contracts on a circuit board of the electronic equipment.

The mobile telephone 10 includes a display 14 and keypad 16. As is conventional, the display 14 displays information to a user such as operating state, time, telephone numbers, contact information, various navigational menus, etc., which enable the user to utilize the various feature of the mobile telephone 10. The display 14 may also be used to visually display content received by the mobile telephone 10 and/or retrieved from a memory 18 (FIG. 2) of the mobile telephone 10.

Similarly, the keypad 16 may be conventional in that it provides for a variety of user input operations. For example, the keypad 16 typically includes alphanumeric keys 20 for allowing entry of alphanumeric information such as telephone numbers, phone lists, contact information, notes, etc. In addition, the keypad 16 typically includes special function keys such as a “call send” key for initiating or answering a call, and a “call end” key for ending, or “hanging up” a call. Special function keys may also include menu navigation keys, for example, for navigating through a menu displayed on the display 14 to select different telephone functions, profiles, settings, etc., as is conventional. Other keys associated with the mobile telephone may include a volume key, an audio mute key, an on/off power key, a web browser launch key, a camera key, etc. Keys or key-like functionality may also be embodied as a touch screen associated with the display 14.

The mobile telephone 10 includes conventional call circuitry that enables the mobile telephone 10 to establish a call and/or exchange signals with a called/calling device, typically another mobile telephone or landline telephone. However, the called/calling device need not be another telephone, but may be some other device such as an Internet web server, content providing server, etc.

FIG. 2 represents a functional block diagram of the mobile telephone 10, the structure of which is generally conventional. The mobile telephone 10 includes a controller 26 as part of a primary control circuit that is configured to carry out overall control of the functions and operations of the mobile telephone 10. The controller 26 may be, for example, a CPU, microcontroller or microprocessor, control circuit, or the like. The controller 26 executes code stored in memory, such as memory 18, in order to carry out conventional operation of the mobile telephone 10. The memory 18 may be, for example, one or more of a buffer, a flash memory, a hard drive, a removable media, a volatile memory, a non-volatile memory or other suitable device. In addition, the controller 26 may execute code in accordance with the present invention in order to control the system for protecting the circuit board 22 of the electronic equipment.

It will be apparent to a person having ordinary skill in the art of computer programming, and specifically in applications programming for mobile telephones or other items of electronic equipment, how to program a mobile telephone 10 to operate and carry out the functions described herein. Accordingly, details as to the specific programming code have been left out for sake of brevity.

Continuing to refer to FIGS. 1 and 2, the mobile telephone 10 includes an antenna 28 coupled to a radio circuit 30, which resides on a circuit board 22. The radio circuit 30 includes a radio frequency transmitter and receiver for transmitting and receiving signals via the antenna 28 as is conventional. The radio circuit 30 may be configured to operate in a mobile communications system. Also residing on the circuit board is a sound signal processing circuit 32 for processing audio signals transmitted by/received from the radio circuit 30. Coupled to the sound processing circuit 32 are a speaker 34 and a microphone 36 that enable a user to listen and speak via the mobile telephone 10 as is conventional. The radio circuit 30 and sound processing circuit 32 are each coupled to the controller 26, such as by of a bus 24, so as to carry out overall operation.

The mobile telephone 10 also includes the aforementioned display 14 and keypad 16 coupled to the circuit board 22. A video decoder (not shown) may be used to convert video data received by the radio circuit 30 or retrieved from a file stored by the memory 18 in to a video signal used to drive the display 14. The mobile telephone 10 may further include any appropriate video and/or audio buffers for buffering video and/or audio data.

The mobile telephone 10 further includes one or more I/O interface(s) 38 on the circuit board 22. The I/O interface(s) 38 may be in the form of typical mobile telephone I/O interfaces and may include one or more electrical connectors. As is typical, the I/O interface(s) 38 may be used to couple the mobile telephone 10 to a battery charger to charge a battery of a power supply unit (PSU) 40 within the mobile telephone 10. In addition, or in the alternative, the I/O interface(s) 38 may serve to connect the mobile telephone 10 to a wired personal hands-free adaptor (not shown). Further, the I/O interface(s) 38 may serve to connect the mobile telephone 10 to a personal computer or other device via a data cable, for example. The mobile telephone 10 may receive operating power via the I/O interface(s) 38 when connected to a vehicle power adapter or an electricity outlet power adapter.

The mobile telephone 10 may also include a timer 42 for carrying out timing functions. Such functions may include timing the durations of calls, generating the content of time and date stamps, etc. The mobile telephone 10 may include a camera 44 for taking digital pictures and/or movies. Image and/or video files corresponding to the pictures and/or movies may be stored in the memory 18. The mobile telephone 10 also may include a position data receiver 46, such as a global positioning system (GPS) receiver. The mobile telephone 10 may also include a timer 42 for carrying out timing functions. Such functions may system receiver or the like. The mobile telephone 10 also may include a local wireless interface 48, such as an infrared transceiver and/or an RF adaptor (e.g., a Bluetooth adaptor), for establishing communication with an accessory, hands-free adaptor, computer or other device.

As indicated, the mobile telephone 10 may be configured to transmit, receive and process data, such as text messages (e.g., in a short message service (SMS) format), multimedia messages (e.g., in a multimedia messaging service (MMS) format), electronic mail messages, image files, video files, audio files, ring tones, streaming audio, streaming video and so forth. Processing such data may include storing the data in the memory 18, executing applications to allow user interaction with data, displaying video and/or image content associated with the data and so forth.

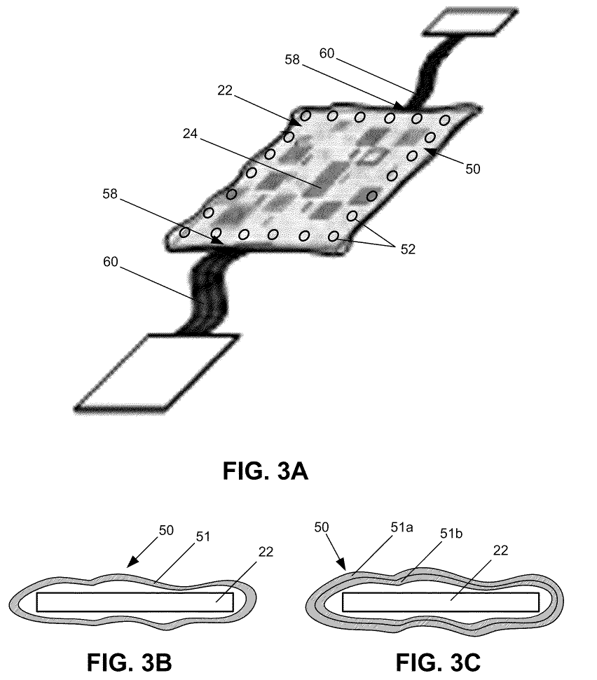

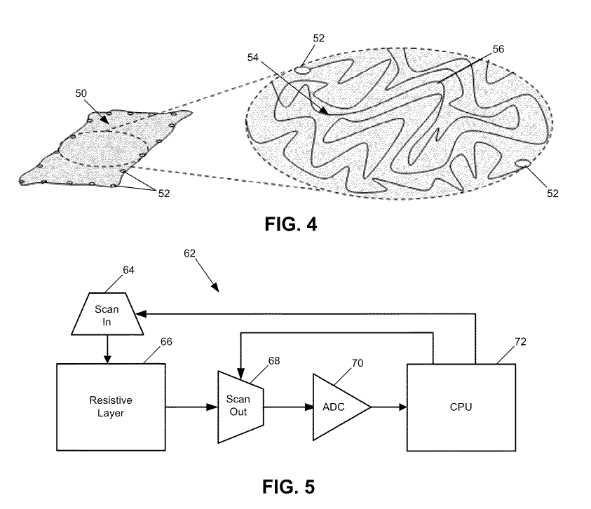

Turning next to FIGS. 3A-C and 4, views of a protected circuit board, such as the circuit board 22, are provided. As shown in FIG. 3A, a circuit board 22 is at least partially enclosed with a protective cover 50, which includes electric contacts 52 coupled to the circuit board 22. The protective cover 50 is preferably formed of a nonconductive material and prevents access to contact points on the circuit board 22. Accordingly, contact points on the circuit board are preferably inaccessible to a probe without removing the protective cover 50. For example, the protective cover 50 may encase the circuit board 22 so that contact points on the circuit board 22 cannot be accessed without cutting through the protective cover 50. Thus, the protective cover 50 provides security against probing of contact points on the circuit board 22, thereby making reverse engineering the circuit board 22 more difficult. More specifically, the protective cover 50 may include at least one nonconductive material layer 51, 51a-b a plurality of electrical contacts 52 coupled to the circuit board 22, and an irregular resistance pattern 54 joined with the at least one layer 51, 51a-b of nonconductive material and coupled to the plurality of the electrical contacts 52. The system may further include a controller 26 that is coupled to the plurality of electrical contacts 52. The controller 26 may be configured to periodically determine the resistance between selected electrical contacts 52, compare the determined resistance between the selected electrical contacts 52 with a prior determined resistance between the selected electrical contacts 52, and indicate a security breach based upon a change in the prior determined resistance and the periodically determined resistance.

The protective cover 50 further includes a resistance pattern 54 connecting contact points 52 to one another. Preferably, the resistance pattern 54 includes a randomized pattern of scan lines 56 between contact points 52. Thus, the resistance between selected contact points 52 may be determined by, for example, the controller 26 on the circuit board 22. In addition and as will be understood by those skilled in the art, any suitable sensors known in the art, such as edge sensors, may be used to determine the resistance of the resistance pattern 54 between selected contacts 52. In one embodiment the protective cover 50 is formed of a mesh of nonconductive material. Preferably, the mesh openings are small enough to prevent probes from contacting any electrical contacts on the circuit board 22. The resistance pattern 54 may be, for example, printed on the protective cover 50 or embedded within the protective cover 50. In one embodiment, the resistance pattern 54 is formed by printing the pattern with conductive ink. In addition, the resistance pattern 54 may be embedded between layers of nonconductive material of the protective cover 50. When encapsulating a circuit board, such as circuit board 22, the protective cover 50 may also include openings 58 through which cables 60 connected to the circuit board 22 may pass for connection to other parts of a system. In addition, when a protective cover, such as the protective cover 50, is used with a portable electronic device, such as a mobile phone, the protective cover may be used to protect electrical contact points on a Subscriber Identity Module SIM card socket.

Turning next to FIG. 5, an exemplary circuit for protecting electrical contacts on a circuit board is disclosed. The circuit 62 begins at the scan in operation 64, which may be performed at a scan in point, such as contact 52. The scan operation is performed over the resistive layer 66, such as the resistance pattern 54. At the scan out operation 68, the resistance across the resistive layer 66 from the scan in point to the scan out point, such as another contact 52, can be identified. In one embodiment the scan from the scan in point, across the resistive layer, to the scan out point is routed through an analog to digital converter (“ADC”) 70 prior to sending scan information to a controller 72, such as the controller 26, which controls the scanning of the resistance layer 66. It will be appreciated by those skilled in the art that the disclosed circuit is a simple exemplary circuit and those skilled in the art will understand that there are a variety of different methods of measuring resistance.

By way of example, the controller 72, such as the controller 26, may generate a scan pattern and sequentially power the scan in points, such as at the contacts 52. The controller 72 then samples the scan out points one by one by way of the ADC 70. The controller 72 may then compare the results received with prior scan results to determine whether there is a sufficient change of conductivity in a particular scan line within a predetermined margin of error that indicates that the protective cover has been tampered with. For example, the controller 72 may be placed on a circuit board, such as circuit board 22, within a protective cover, such as protective cover 50. At first power up, the scan lines 56 of the resistance pattern 54 may be sampled using a predetermined pattern. The scanning results may then be stored in memory, such as memory 18, which may be non-volatile, coupled to the controller 72. In addition, although less secure, a command, such as an AT command, may be used to store baseline readings in memory. In addition, the scan sequence, voltages used for scanning and ADC readings may be randomized to improve security.

Following storage of baseline readings in memory, the scan lines 56 of the resistance pattern 54 are periodically scanned and the results are compared to the baseline results from a prior scan, which are retrieved from memory. In addition, the readings from the periodic scanning may also be stored in memory. Moreover, results generated by the scan immediately prior to the current scan may be the baseline results used for comparison. Preferably, the baseline resistance values of the scan lines 56 are generated such that they cannot be duplicated by simply measuring the resistance between contacts 52.

Accordingly, as shown in the system illustrated in FIGS. 3A-C and 4-5 a circuit board, such as circuit board 22, may be covered by a protective cover, such as protective cover 50. The protective cover 50 may include at least one nonconductive material layer, a plurality of electrical contacts, such as contacts 52, coupled to the circuit board, and an irregular resistance pattern, such as resistance pattern 54, joined with the at least one layer of nonconductive material and coupled to the plurality of the electrical contacts. A first set of two of the plurality of electrical contacts may then be selected and the resistance between the first set of electrical contacts may be determined. The resistance may then be stored in memory, such as memory 18. In addition, the determined resistance may be converted from analog to digital form, and such conversion may occur prior to storing the resistance in memory. The determined resistance may then be compared with a prior determined resistance between the first set of electrical contacts. A security breach may then be indicated based upon a change in the prior determined resistance between the first set of electrical contacts and the determined resistance between the first set of electrical contacts. The amount of change indicative of a security breach may vary based on a predetermined margin of error.

A second set of electrical contacts may then be selected such that at least one of the second set of two electrical contacts is different from the electrical contacts in the first set of two electrical contacts. The resistance between the second set of two contacts may also be determined, and then compared to a prior determined resistance between the second set of two contacts. A security breach may be indicated based upon a change in the prior determined resistance between the second set of two contacts and the determined resistance between the second set of two contacts. In addition, these steps may be repeated for a plurality of different desired second sets of two of the plurality electrical contacts.

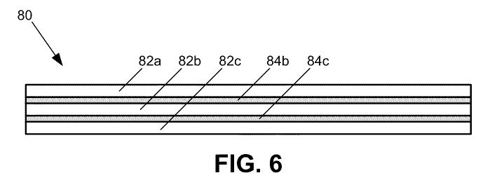

Turning next to FIG. 6, a diagrammatic illustration of a system having protective layers between layers of a circuit board is provided. The system 80 includes a circuit board having multiple layers 82a-c. Disposed between the layers 82a-c are layers of protective material, such as the material of protective cover 50. Like the material of protective cover 50, the protective layers 84a-b may be nonconductive. Also like the protective cover, the protective layers 84a-b may each include an irregular resistance pattern and scan lines connecting electrical contacts (see FIG. 3A). Using the same methodology described above with respect to the protective cover, the resistance patterns of the protective layers 84a-b may be scanned and compared to prior scans to determine when a breach has occurred between layers 82a-c of the circuit board 80.

Although the invention has been shown and described with respect to certain preferred embodiments, it is obvious that equivalents and modifications will occur to others skilled in the art upon the reading and understanding of the specification. The present invention includes all such equivalents and modifications, and is limited only by the scope of the following claims.

1. A system for protecting electrical contact points on a circuit board comprising:
a protective cover preventing access to electrical contact points on the circuit board, the protective cover comprising:
at least one nonconductive material layer,
a plurality of electrical contacts coupled to the circuit board, and
an irregular resistance pattern joined with the at least one layer of nonconductive material and coupled to the plurality of the electrical contacts; and
a controller coupled to the plurality of electrical contacts and configured to:
periodically determine the resistance between selected electrical contacts,
compare the determined resistance between the selected electrical contacts with a prior determined resistance between the selected electrical contacts, and
indicate a security breach based upon a change in the prior determined resistance and the periodically determined resistance.

2. The system of claim 1 further comprising a memory for storing the prior determined resistance between the selected electrical contacts.

3. The system of claim 2 wherein the controller is further configured to store the periodically determined resistance in memory.

4. The system of claim 3 wherein the periodically determined resistance from a first determination is the prior determined resistance in a second determination.

5. The system of claim 1 wherein the controller is further configured to sequentially select the selected electrical contacts.

6. The system of claim 1 wherein the irregular resistance pattern comprises scan lines between the selected electrical contacts.

7. The system of claim 6 further comprising an analog to digital converter for converting signals received over scan lines to digital form.

8. The system of claim 1 wherein the nonconductive material layer is a mesh layer.

9. The system of claim 1 wherein the irregular resistance pattern comprises resistive ink printed on the nonconductive material layer.

10. The system of claim 1 wherein the irregular resistance pattern is embedded within multiple layers of nonconductive material.

11. The system of claim 1 wherein the irregular resistance pattern is a randomized pattern.

12. The system of claim 1 wherein the nonconductive material layer further comprises at least one opening through which cables connected to the circuit board can exit the protective cover.

13. The system of claim 1 wherein a Subscriber Identity Module card socket comprises the electrical contact points.

14. A multilayer tamper evidencing circuit board comprising:
a first circuit board layer;
a second circuit board layer; and
a tamper evidencing layer between the first circuit board layer and the second circuit board layer, the tamper evidencing layer comprising:
at least one nonconductive material layer,
a plurality of electrical contacts coupled to at least one of the first circuit board layer or the second circuit board layer, and
an irregular resistance pattern joined with the at least one layer of nonconductive material and coupled to the plurality of the electrical contacts.

15. The multilayer tamper evidencing circuit board of claim 14 further comprising a controller coupled to the plurality of electrical contacts and configured to:
periodically determine the resistance between selected electrical contacts,
compare the determined resistance between the selected electrical contacts with a prior determined resistance between the selected electrical contacts, and
indicate a security breach based upon a change in the prior determined resistance and the periodically determined resistance.

16. A method for protecting electrical contact points on a circuit board comprising:
covering electrical contact points on the circuit board with a protective cover comprising:
at least one nonconductive material layer,
a plurality of electrical contacts coupled to the circuit board, and
an irregular resistance pattern joined with the at least one layer of nonconductive material and coupled to the plurality of the electrical contacts;
selecting a first set of two of the plurality of electrical contacts;
determining the resistance between the first set of electrical contacts;
comparing the determined resistance between the first set of electrical contacts with a prior determined resistance between the first set of electrical contacts; and
indicating a security breach based upon a change in the prior determined resistance between the first set of electrical contacts and the determined resistance between the first set of electrical contacts.

17. The method of claim 16 further comprising storing in memory the prior determined resistance between the selected electrical contacts.

18. The method of claim 16 further comprising converting the determined resistance from analog to digital form.

19. The method of claim 16 further comprising:
selecting a second set of two of the plurality of electrical contacts such that at least one of the second set of two electrical contacts is different from the electrical contacts in the first set of two electrical contacts;
determining the resistance between the second set of two contacts;
comparing the determined resistance between the second set of two contacts with a prior determined resistance between the second set of two contacts; and
indicating a security breach based upon a change in the prior determined resistance between the second set of two contacts and the determined resistance between the second set of two contacts.

20. The method of claim 19 further comprising repeating the steps of claim 19 for a plurality of different desired second sets of two of the plurality electrical contacts.
